(19) United States
(12) Patent Application Publication
(10) Pub. No.: US 2025/0119487 A1
(43) Pub. Date: Apr. 10, 2025

(54) ELECTRONIC DEVICE INCLUDING DIGITIZER

(71) Applicant: Samsung Electronics Co., Ltd., Suwon-si (KR)

(72) Inventors: Jaedeok LIM, Suwon-si (KR); Sangil PARK, Suwon-si (KR); Jaehyoung YOU, Suwon-si (KR); Chulhyo YOON, Suwon-si (KR); Gyuyeong CHO, Suwon-si (KR); Hyein PARK, Suwon-si (KR)

(21) Appl. No.: 18/984,623

(22) Filed: Dec. 17, 2024

Related U.S. Application Data
(63) Continuation of application No. PCT/KR2023/011877, filed on Aug. 10, 2023.

(30) Foreign Application Priority Data
Aug. 12, 2022 (KR) 10-2022-0101435
Oct. 31, 2022 (KR) 10-2022-0142384

(51) Int. Cl. H04M 1/02

(52) U.S. Cl. CPC H04M 1/0266; H04M 1/0216; H04M 1/0264; H04M 2250/22

(57) ABSTRACT

An electronic device may be provided. The electronic device may comprise: a housing; a display; a digitizer disposed under the display; an absorber sheet disposed under the digitizer; and a metal sheet disposed under the absorber sheet. The absorber sheet may comprise: first particles containing iron, silicon, and aluminum; and second particles containing iron and silicon. The ratio of the second particles to the first particles may be 7:3 or greater.

### CROSS-REFERENCE TO RELATED APPLICATIONS

This application is a continuation of International Application No. PCT/KR2023/011877 designating the United States, filed on Aug. 10, 2023, in the Korean Intellectual Property Receiving Office and claiming priority to Korean Patent Application Nos. 10-2022-0101435, filed on Aug. 12, 2022, and 10-2022-0142384, filed on Oct. 31, 2022, in the Korean Intellectual Property Office, the disclosures of each of which are incorporated by reference herein in their entireties.

### BACKGROUND

### Field

The disclosure relates to an electronic device including a digitizer.

### Description of Related Art

Due to advancement in information and communication technology and semiconductor technology, various functions are being integrated into a single portable electronic device. For example, an electronic device may implement not only communication functions, but also entertainment functions such as gaming, multimedia functions such as music/video playback, communication and security functions for mobile banking or the like, and functions for schedule management and an electronic wallet function. These electronic devices are being miniaturized to be conveniently carried by users.

An electronic device may receive various inputs from a user via an input device (e.g., a digital pen). The electronic device may identify a position on the electronic device designated by the input device and may perform a corresponding function. For example, the electronic device may identify a position on the electronic device designated by the input device using an electromagnetic resonance (hereinafter, referred to as “EMR”) method or an active electrostatic (hereinafter, referred to as “AES”) method.

### SUMMARY

According to an example embodiment of the disclosure, an electronic device may include: a housing, a display, a digitizer positioned under the display, an absorber sheet positioned under the digitizer, and a metal sheet positioned under the absorber sheet. The absorber sheet may include first particles including iron, silicon, and aluminum, and second particles including iron and silicon. The ratio of the second particles to the first particles may be at least 7:3.

According to an example embodiment of the disclosure, a foldable electronic device may include: a housing including a first housing and a second housing, a display including a first display area positioned on the first housing, a second display area positioned on the second housing, and a folding area positioned between the first display area and the second display area, a hinge structure comprising a hinge connecting the first housing and the second housing, in which at least a portion of the hinge structure is positioned under at least a portion of the folding area, a digitizer positioned under the display, and an absorber sheet positioned under the digitizer. The absorber sheet may include first particles including iron, silicon, and aluminum, and second particles including iron and silicon. The ratio of the second particles to the first particles may be 7:3 or higher.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to an embodiment of the disclosure

FIG. 2 is a diagram illustrating an example electronic device in an unfolded state according to an embodiment of the disclosure;

FIG. 3 is a diagram illustrating the electronic device of FIG. 2 in a folded state according to an embodiment of the disclosure;

FIG. 4 is an exploded perspective view of an electronic device according to an embodiment of the disclosure;

FIG. 5 is a diagram illustrating an example operation of a digital pen according to an embodiment of the disclosure;

FIG. 6 is a block diagram illustrating an example configuration of a digital pen according to an embodiment of the disclosure;

FIG. 7 is diagram illustrating an enlarged view of an absorber sheet according to an embodiment of the disclosure;

FIG. 8A is a graph illustrating the permeability of first particles of an absorber sheet according to an embodiment of the disclosure;

FIG. 8B is a graph illustrating the permeability of second particles of an absorber sheet according to an embodiment of the disclosure;

FIG. 9 is a cross-sectional view of an electronic device including an electronic component according to an embodiment of the disclosure;

FIG. 10 is a cross-sectional view of an electronic device including a hinge structure according to an embodiment of the disclosure; and

FIG. 11 is a diagram illustrating a shielding member attached to a housing according to an embodiment of the disclosure.

### DETAILED DESCRIPTION

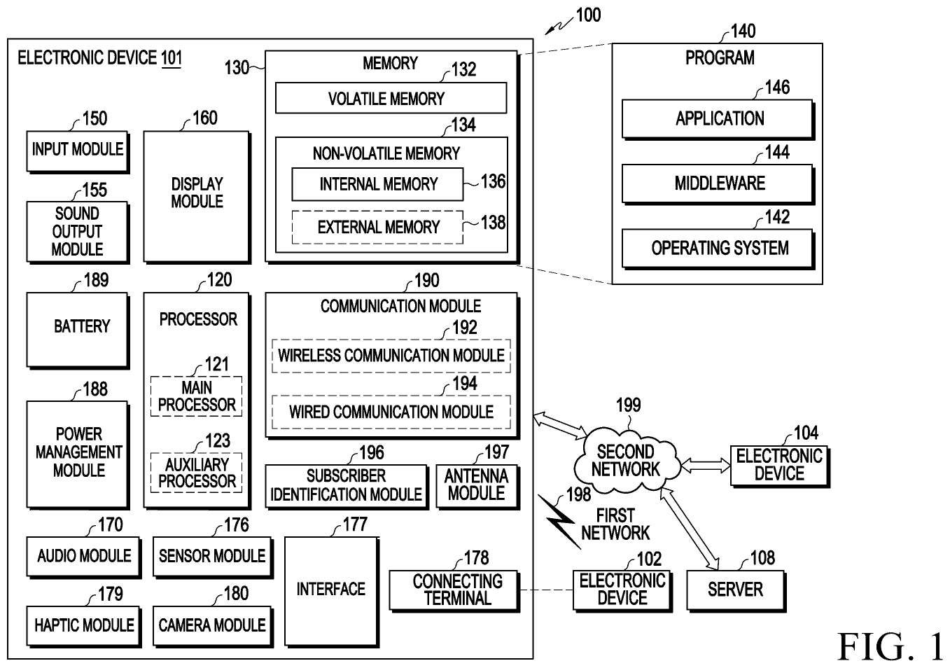

FIG. 1 is a block diagram illustrating an example electronic device in a network environment according to an embodiment of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

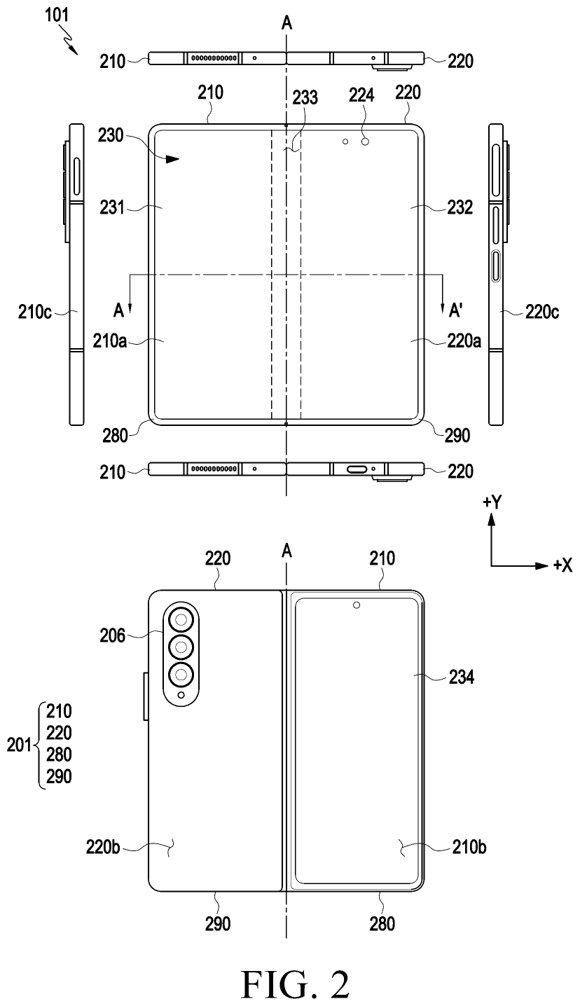

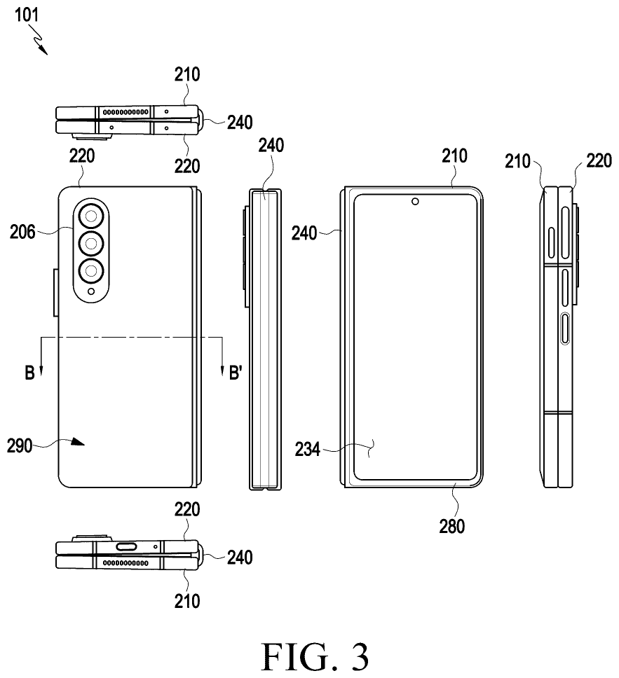

FIG. 2 is a diagram illustrating an example electronic device in an unfolded state according to an embodiment of the disclosure. FIG. 3 is a diagram illustrating the electronic device of FIG. 2 in a folded state according to an embodiment of the disclosure.

Referring to FIGS. 2 and 3, an electronic device 101 may include a housing 201, a hinge cover 240 configured to cover a foldable portion of the housing 201, and a display 230 disposed in a space defined by the housing 201. According to an embodiment, the surface on which a screen output from the display 230 is visible is defined as the front surface of the electronic device 101 (e.g., a first front surface 210a and a second front surface 220a). The surface opposite to the front surface is defined as the rear surface (e.g., a first rear surface 210b and a second rear surface 220b) of the electronic device 101. In addition, a surface surrounding the space between the front and rear surfaces is defined as the side surface (e.g., a first side surface 210c and a second side surface 220c) of the electronic device 101. The side surface of the electronic device 101 may be the side surface of at least one of the first housing 210 or the second housing 220. The electronic device 101 of FIGS. 2 and 3 may be referred to as a “foldable electronic device”, a “portable electronic device”, or a “portable foldable electronic device”. According to an embodiment, the housing 201 may be referred to as a “foldable housing”.

According to an embodiment, the housing 201 may include a first housing 210, a second housing 220 rotatable with respect to the first housing 210, a first rear surface cover 280, and a second rear surface cover 290. The housing 201 of the electronic device 101 is not limited to the shape and assembly illustrated in FIGS. 2 and 3, but may be implemented by combinations and/or assemblies of other shapes or components. For example, in an embodiment, the first housing 210 and the first rear surface cover 280 may be integrally configured, and the second housing 220 and the second rear surface cover 290 may be integrally configured.

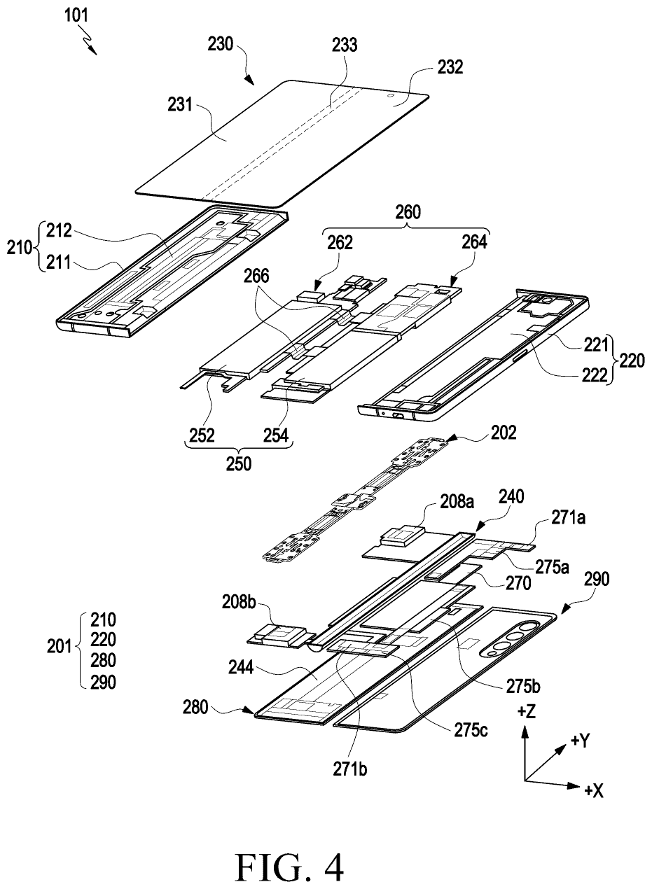

According to an embodiment, the first housing 210 may include a first front surface 210a connected to a hinge structure (e.g., the hinge structure 202 in FIG. 4) and oriented in a first direction and a first rear surface 210b oriented in a second direction opposite to the first direction. The second housing 220 may include a second front surface 220a connected to the hinge structure 202 and oriented in a third direction, and a second rear surface 220b oriented in a fourth direction opposite to the third direction, and may be rotatable with respect to the first housing 210 around the hinge structure 202. Accordingly, the electronic device 101 may be changed to a folded state or an unfolded state. When the electronic device 101 is in the folded state, the first front surface 210a may face the second front surface 220a, and when the electronic device 101 is in the unfolded state, the third direction may be the same as the first direction. Hereinbelow, unless otherwise stated, directions will be described with reference to the unfolded state of the electronic device 101.

According to an embodiment, the first housing 210 and the second housing 220 may be disposed on opposite sides about the folding axis A and may have generally symmetrical shapes with respect to the folding axis A. As will be described later, the angle or distance between the first housing 210 and the second housing 220 may vary depending on whether the electronic device 101 is in the unfolded state, in the folded state, or in the intermediate state. According to an embodiment, the second housing 220 additionally includes a sensor area 224 where sensors (e.g., a front camera) are disposed, but the second housing 220 may have a symmetrical shape with respect to the first housing 210 in other areas.

According to an embodiment, the folding axis A may be a plurality of (e.g., two) parallel folding axes. In the disclosure, the folding axis A is provided along the longitudinal direction (the Y-axis direction) of the electronic device 101, but the direction of the folding axis A is not limited thereto. For example (not illustrated), the electronic device 101 may include a folding axis A extending along the width direction (e.g., the X-axis direction).

According to an embodiment, the electronic device 101 may include a structure to which a digital pen can be attached. For example, the electronic device 101 may include a magnetic body configured to attach the digital pen to the side surface of the first housing 210 or the side surface of the second housing 220. According to an embodiment, the electronic device 101 may include a structure into which a digital pen is insertable. For example, a hole (not illustrated) into which the digital pen is insertable may be provided in the side surface of the first housing 210 or the side surface of the second housing 220 of the electronic device 101.

According to an embodiment, the first housing 210 and the second housing 220 may be at least partially made of a metal or non-metal material having rigidity in a level selected in order to support the display 230. The at least a portion made of the metal material may provide a ground plane of the electronic device 101, and may be electrically connected to a ground line provided on a printed circuit board (e.g., the board unit 260 in FIG. 4).

According to an embodiment, the sensor area 224 may be defined to have a predetermined area adjacent to an edge or a corner of the second housing 220. However, the arrangement, shape, and size of the sensor area 224 are not limited to the illustrated example. For example, in an embodiment, the sensor area 224 may be provided at another corner or at any area between the upper and lower end corners in the second housing 220 or in the first housing 210. In an embodiment, components embedded in the electronic device 101 to carry out various functions may be exposed on the front surface of the electronic device 101 through the sensor area 224 or through one or more openings provided in the sensor area 224. In an embodiment, the components may include various types of sensors. The sensors may include, for example, at least one of a front camera, a receiver, or a proximity sensor.

According to an embodiment, the first rear surface cover 280 may be disposed on the rear surface of the electronic device 101 on one side of the folding axis A and may have, for example, a substantially rectangular periphery, which may be surrounded by the first housing 210. Similarly, the second rear surface cover 290 may be arranged on the other side of the folding axis A of the rear surface of the electronic device 101, and the periphery of the second rear surface cover 290 may be enclosed by the second housing 220.

According to an embodiment, the first rear surface cover 280 and the second rear surface cover 290 may have substantially symmetrical shapes about the folding axis (the axis A). However, the first rear surface cover 280 and the second rear surface cover 290 do not necessarily have mutually symmetrical shapes, and in an embodiment, the electronic device 101 may include a first rear surface cover 280 and a second rear surface cover 290 having various shapes.

According to an embodiment, the first rear surface cover 280, the second rear surface cover 290, the first housing 210, and the second housing 220 may define a space in which various components (e.g., a printed circuit board or a battery) of the electronic device 101 may be disposed. According to an embodiment, one or more components may be disposed or visually exposed on the rear surface of the electronic device 101. For example, at least a portion of the sub-display (e.g., the sub-display 244 in FIG. 4) may be visible through at least a portion of the first rear surface cover 280. In an embodiment, one or more components or sensors may be visually exposed through at least a portion of the second rear surface cover 290. In an embodiment, the sensors may include a proximity sensor and/or a camera module 206 (e.g., a rear camera).

According to an embodiment, a front camera exposed to the front surface of the electronic device 101 through one or more openings provided in the sensor area 224 or a camera module 206 exposed through at least a portion of the second rear surface cover 290 may include one or more lenses, an image sensor, and/or an image signal processor. In an embodiment, two or more lenses (e.g., an infrared camera, a wide-angle lens, and a telephoto lens), and image sensors may be arranged on one surface of the electronic device 101.

According to an embodiment, the hinge cover 240 is disposed between the first housing 210 and the second housing 220 and may cover internal components (e.g., the hinge structure 202 in FIG. 4). According to an embodiment, the hinge cover 240 may be covered by a portion of the first housing 210 and a portion of the second housing 220, or may be exposed to the outside depending on the state of the electronic device 101 (the unfolded state (flat state) or the folded state).

According to an embodiment, as illustrated in FIG. 2, when the electronic device 101 is in the unfolded state, the hinge cover 240 may not be exposed by being covered by the first housing 210 and the second housing 220. As another example, as illustrated in FIG. 3, when the electronic device 101 is in the folded state (e.g., the fully folded state), the hinge cover 240 may be exposed to the outside between the first housing 210 and the second housing 220. As another example, when the first housing 210 and the second housing 220 are in the intermediate state in which the first and second housings are folded with a certain angle therebetween, the hinge cover 240 may be partially exposed to the outside between the first housing 210 and the second housing 220. However, in this case, the exposed area may be smaller than that in the fully folded state. According to an embodiment, the hinge cover 240 may include a curved surface.

According to an embodiment, the display 230 may be placed in the space defined by the housing 201. For example, the display 230 may be seated in a recess defined by the housing 201, and may constitute most of the front surface of the electronic device 101. Accordingly, the front surface of the electronic device 101 may include the display 230, and partial areas of the first housing 210 and the second housing 220, which are adjacent to the display 230. The rear surface of the electronic device 101 may include the first rear surface cover 280, a partial area of the first housing 210 adjacent to the first rear surface cover 280, the second rear surface cover 290, and a partial area of the second housing 220 adjacent to the second rear surface cover 290.

According to an embodiment, the display 230 may refer to a display that is at least partially deformable into a planar surface or a curved surface. For example, the display 230 may be a foldable or flexible display. According to an embodiment, the display 230 may include a folding area 233, a first display area 231 disposed on one side of the folding area 233 (e.g., the left side of the folding area 233 illustrated in FIG. 2), and a second display area 232 disposed on the other side of the folding area 233 (e.g., the right side of the folding area 203 illustrated in FIG. 2).

According to an embodiment, the display 230 may include a first display area 231 disposed on the first housing 210, a second display area 232 disposed on the second housing 220, and a folding area 233 positioned between the first display area 231 and the second display area 232. According to an embodiment, the first display area 231 and the second display area 232 may be rotatable about the folding axis A.

However, the area division of the display 230 is illustrative, and the display 230 may be divided into multiple areas (e.g., four or more areas or two areas) depending on the structure or functions thereof. For example, in the embodiment illustrated in FIG. 2, the area of the display 230 may be divided by the folding area 233 or the folding axis (the axis A) extending parallel to the Y axis. However, in an embodiment, the area of the display 230 may be divided based on another folding area (e.g., a folding area parallel to the X axis) or another folding axis (e.g., a folding axis parallel to the X axis). According to an embodiment, the display 230 may be coupled to or disposed adjacent to a touch-sensitive circuit, a pressure sensor that is capable of measuring touch intensity (pressure), and/or a digitizer (not illustrated) configured to detect a magnetic field-type stylus pen.

According to an embodiment, the first display area 231 and the second display area 232 may have generally symmetrical shapes about the folding area 233. According to an embodiment (not illustrated), unlike the first display area 231, the second display area 232 may include a notch cut due to the presence of the sensor area 224, but may have a shape symmetrical to the first display area 231 in areas other than the sensor area. In other words, the first display area 231 and the second display area 232 may include portions having mutually symmetrical shapes and portions having mutually asymmetrical shapes.

Hereinafter, the operations of the first housing 210 and the second housing 220 depending on the states of the electronic device 101 (e.g., a flat or unfolded state and a folded state) and respective areas of the display 230 will be described.

According to an embodiment, when the electronic device 101 is in the unfolded state (the flat state) (e.g., FIG. 2), the first housing 210 and the second housing 220 may be disposed to form an angle of 180 degrees therebetween and to be oriented in the same direction. The surface of the first display area 231 and the surface of the second display area 232 of the display 230 may form 180 degrees therebetween and may oriented in the same direction (e.g., the front direction of the electronic device). The folding area 233 may define the same plane as the first display area 231 and the second display area 232.

According to an embodiment, when the electronic device 101 is in the folded state (e.g., FIG. 3), the first housing 210 and the second housing 220 may be disposed to face each other. The surface of the first display area 231 and the surface of the second display area 232 of the display 230 may face each other while forming a narrow angle (e.g., between 0 degrees and 10 degrees) therebetween. At least a portion of the folding area 233 may be provided as a curved surface having a predetermined curvature.

According to an embodiment, when the electronic device 101 is in the intermediate state (not illustrated), the first housing 210 and the second housing 220 may be disposed to form a certain angle therebetween. The surface of the first display area 231 and the surface of the second display area 232 of the display 230 may form an angle greater than that in the folded state and smaller than that in the unfolded state. At least a portion of the folding area 233 may form a curved surface having a predetermined curvature, and the curvature in this case may be smaller than that in the folded state.

FIG. 4 is an exploded perspective view of an electronic device according to an embodiment of the disclosure.

Referring to FIG. 4, the electronic device 101 may include a housing 201, a display 230, a hinge structure 202, a battery 250, and a board unit 260. The housing 201 may include a first housing 210, a second housing 220, a first rear surface cover 280, and a second rear surface cover 290. The configuration of the first housing 210, the second housing 220, the hinge cover 240, the first rear surface cover 280, and the second rear surface cover 290 of FIG. 4 may be wholly or partly the same as the configuration of the first housing 210, the second housing 220, the hinge cover 240, the first rear surface cover 280, and the second rear surface cover 290 in FIG. 2 and/or FIG. 3.

According to an embodiment, the first housing 210 and the second housing 220 may be assembled to each other to be coupled to opposite sides of the hinge structure 202. According to an embodiment, the first housing 210 may include a first support area 212 capable of supporting components (e.g., the first circuit board 262 and/or the first battery 252) of the electronic device 101 and a first side wall 211 surrounding at least a portion of the first support area 212. The first side wall 211 may include a first side surface (e.g., the first side surface 210c in FIG. 2) of the electronic device 101. According to an embodiment, the second housing 220 may include a second support area 222 capable of supporting components (e.g., the second circuit board 264 and/or the second battery 254) of the electronic device 101 and a second side wall 221 surrounding at least a portion of the second support area 222. The second side wall 221 may include a second side surface (e.g., the second side surface 220c in FIG. 2) of the electronic device 101.

According to an embodiment, the display 230 may include a first display area 231, a second display area 232, a folding area 233, and a sub-display 244. The configuration of the first display area 231, the second display area 232, and the folding area 233 in FIG. 3 may be wholly or partly the same as or similar to the configuration of the first display area 231, the second display area 232, and the folding area 233 in FIG. 1 and/or FIG. 2.

According to an embodiment, the sub-display 244 may display a screen in a different direction from the display areas 231 and 232. For example, the sub-display 234 may output a screen in a direction opposite to the first display area 231. According to an embodiment, the sub-display 234 may be disposed on the first rear surface cover 280.

According to an embodiment, the battery 250 may include a first battery 252 disposed in the first housing 210 and a second battery 254 disposed in the second housing 220. According to an embodiment, the first battery 252 may be connected to a first circuit board 262, and the second battery 254 may be connected to a second circuit board 264. According to an embodiment, the battery 250 may supply power to at least one component of the electronic device 101. According to an embodiment, the battery 250 may include, for example, a non-rechargeable primary cell, a rechargeable secondary cell, or a fuel cell.

According to an embodiment, the board unit 260 may include the first circuit board 262 disposed in the first housing 210 and the second circuit board 264 disposed in the second housing 220. According to an embodiment, the first circuit board 262 and the second circuit board 264 may be electrically connected to each other by at least one flexible circuit board 266. According to an embodiment, at least a portion of flexible circuit board 266 may be disposed across hinge structure 202. According to an embodiment, the first circuit board 262 and the second circuit board 264 may be disposed in a space defined by the first housing 210, the second housing 220, the first rear surface cover 280, and the second rear surface cover 290. Components for implementing various functions of the electronic device 101 may be mounted on the first circuit board 262 and the second circuit board 264.

According to an embodiment, the electronic device 101 may include speakers 208a and 208b. According to an embodiment, the speakers 208a and 208b may convert electrical signals into sound. According to an embodiment, the speakers 208a and 208b may be disposed inside the space defined by the first housing 210, the second housing 220, the first rear surface cover 280, and the second rear surface cover 290. According to an embodiment, the speakers 208a and 208b may include an upper speaker 208a located in an upper portion (the +Y direction) of the electronic device 101 and a lower speaker 208b located in the lower portion (the −Y direction) of the electronic device 101. In the disclosure, the speakers 208a and 208b are illustrated as being located within one housing (e.g., the first housing 210 in FIG. 4), but this is an optional structure. For example, the speakers 208a and 208b may be located within at least one of the first housing 210 or the second housing 220. The configuration of the speakers 208a and 208b in FIG. 4 may be wholly or partly the same as the configuration of the sound output module 155 in FIG. 1.

According to an embodiment, the electronic device 101 may include a rear member 270 (or a rear case). According to an embodiment, the rear member 270 may be disposed within the housing 201 (e.g., the second housing 220). According to an embodiment, the rear member 270 may accommodate at least one antenna 275.

According to an embodiment, the electronic device 101 may include an antenna 275. The antennas 275a and 275b may include, for example, an ultrawide band (UWB) antenna 275a, a near field communication (NFC) antenna, a wireless charging antenna, and/or a magnetic secure transmission (MST) antenna 275b. For example, the antenna 275 may execute short-range communication with an external device or may transmit/receive power required for charging to/from an external device in a wireless manner.

In an embodiment, an antenna structure may be provided by portions of the housing 201 or a combination thereof. For example, the antenna 275 may include a communication antenna 275c that is at least partially exposed to the outside of the electronic device 101 and defines at least a portion of the outside of the electronic device 101. The communication antenna 275c may be used for communication (e.g., Wi-Fi) with an external electronic device. The communication antenna 275c may be connected to an upper portion 271a or a lower portion 271b of the rear member 270.

In the following detailed description, a pair of housings may be illustrated with respect to a configuration in which the housings are rotatably coupled to each other by a hinge structure. It is noted that an electronic device according to various embodiments disclosed herein is not limited by the various embodiments. For example, an electronic device according to various embodiments disclosed herein may include three or more housings, and the “a pair of housings” in the embodiments disclosed below may refer, for example, to “two housings rotatably coupled to each other among three or more housings”.

Herein, the electronic device 101 is described as having a structure of a foldable electronic device, but the structure of the electronic device 101 is not limited thereto. For example, the electronic device 101 may be a tablet or a bar-shaped smartphone.

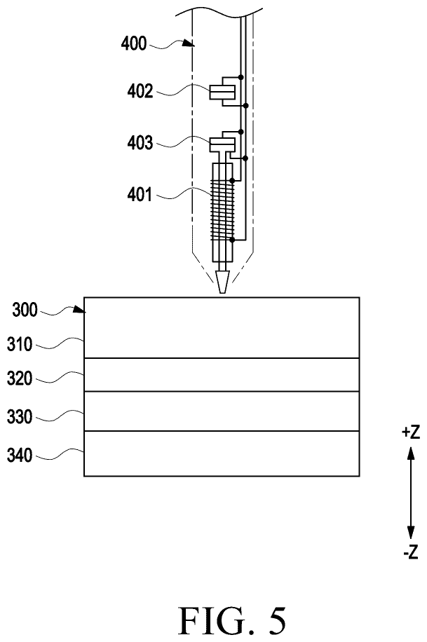

FIG. 5 is a diagram illustrating an example operation of a digital pen according to an embodiment of the disclosure.

Referring to FIG. 5, the electronic device 300 may include a display 310, a digitizer 320, an absorber sheet 330, and a metal sheet 340. The configurations of the electronic device 101 and the display 310 of FIG. 5 may be wholly or partly the same as the configurations of the electronic device 101 and the display 230 of FIG. 2, FIG. 3, and/or FIG. 4.

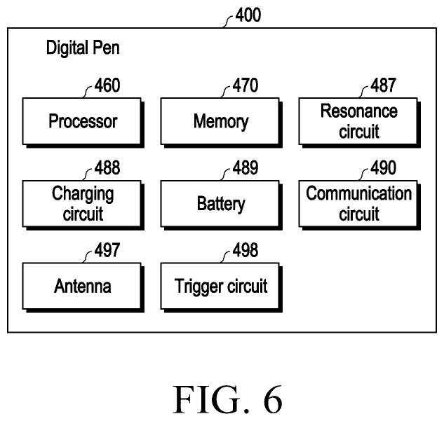

According to an embodiment, the digitizer 320 may be a panel configured to detect an input from a digital pen (e.g., the digital pen 400 in FIG. 6) (e.g., an electromagnetic inductor). The digitizer 320 may be referred to as an electromagnetic induction panel. The digital pen may provide an input to the electronic device 101 using an electro-magnetic resonance (EMR), active electrical stylus (AES), or electric coupled resonance (ECR) method. The digital pen may be referred to as a stylus. For example, the digitizer 320 may include a circuit board (e.g., a printed circuit board or a flexible printed circuit board) and a plurality of coils positioned within the circuit board. The plurality of coils may generate a magnetic field. The digital pen may resonate based on the magnetic field generated from the digitizer, and a magnetic field may be formed in the coils of the digital pen by the resonance. A current may be output from the coils of the digitizer 320 by the magnetic field formed from the digital pen. The electronic device 101 may identify (or detect) the position of the digital pen 400 based on the magnitude of the current (e.g., converted digital values) per channel output from the plurality of coils of the digitizer 320. According to an embodiment, the digitizer 320 may include a pattern layer on which a transmission pattern is formed and a pattern layer on which a reception pattern is formed. The transmission pattern and the reception pattern layers may be mutually laminated to generate or detect an electromagnetic field. The electronic device 101 may detect a magnetic field generated from the digital pen through the EMR method using the digitizer 320 and may detect various motions such as approaching, clicking, or dragging of the digital pen. According to an embodiment, the digitizer 320 may include coils 321 and 321 capable of generating a magnetic field based on the movement of the digital pen 400. For example, the digitizer 320 may include a first coil 321 facing the display 310 and a second coil 322 facing the absorber sheet 330.

According to an embodiment, the digitizer 320 may be referred to as a part of the display 310. For example, the display 310 and the digitizer 320 may be provided as a single modularized component (e.g., a display assembly).

According to an embodiment, the absorber sheet 330 may enhance the sensitivity for detecting an input (e.g., proximity) of the digital pen 400. For example, the absorber sheet 330 may increase the inductance of a coil 401 of the digital pen 400. For example, the absorber sheet 330 may have a predetermined (e.g., specified) permeability and/or thickness to increase the inductance of the coil 401. According to an embodiment, the absorber sheet 330 may support the digitizer 320. For example, the absorber sheet 330 may be positioned under the digitizer (320) (in the −Z direction).

According to an embodiment, the absorber sheet 330 may reduce electromagnetic interference of the digitizer 320. According to an embodiment, the absorber sheet 330 may include magnetic metal powder. For example, the absorber sheet 330 may be referred to as a layer of magnetic metal powder applied under the digitizer 320. The absorber sheet 330 may reduce the magnitude of the magnetic field of the electronic component, which is positioned within the housing (e.g., the housing 201 in FIG. 4), to be transmitted to the digitizer 320 in addition to the signal input from the digital pen. By reducing the magnetic field of the electronic component, which is positioned within the electronic device 101, to be transmitted to the digitizer 320, the noise of the digitizer 320 may be reduced. According to an embodiment, the absorber sheet 330 may be referred to as a high-frequency absorber sheet.

According to an embodiment, the metal sheet 340 may provide uniform inductance. For example, the metal sheet 340 may include a metal (e.g., copper) and may reduce the destructive interference due to an eddy current. For example, the metal sheet 340 may reduce the eddy current generated in the digitizer 320 by allowing at least a portion of the magnetic field passing through the digitizer 320 and the absorber sheet 330 to flow inside the metal sheet 340.

According to an embodiment, the metal sheet 340 may support the digitizer 320 and/or the absorber sheet 330. For example, the metal sheet 340 may be disposed under the absorber sheet 330 (in the −Z direction). According to an embodiment, the metal sheet 340 may be referred to as a support sheet or a support plate.

According to an embodiment, the digital pen 400 may respond to a magnetic field generated from the digitizer 320. For example, the digital pen 400 may include a coil 401 configured to resonate based on the magnetic field generated from the digitizer 320. The digital pen 400 may generate a magnetic field using the resonance of the coil 401. The digitizer 320 may output a current based on the magnetic field generated from the digital pen 400.

According to an embodiment, the digital pen 400 may store power using a capacitor. For example, the digital pen 400 may include at least one variable capacitor 402 and at least one fixed capacitor 403.

According to an embodiment, the memory (e.g., the memory 130 in FIG. 1) of the electronic device 300 may store a calibration value for the operation of the digital pen 400 in a state of no interference. The processor (e.g., the processor 120 in FIG. 1) of the electronic device 300 may determine an input of the digital pen 400 using the calibration value stored in the memory 130. However, when the magnetic permeability of the digitizer 320 and/or the absorber sheet 330 changes due to a magnetic field generated from a surrounding magnet, the accuracy of the processor 120 in determining the position of the digital pen 400 may decrease. The absorber sheet 330 may have a saturation magnetic flux density value to reduce the change in permeability.

FIG. 6 is a block diagram illustrating an example configuration of a digital pen according to an embodiment of the disclosure.

Referring to FIG. 6, the digital pen 400 may include a processor (e.g., including processing circuitry) 460, a memory 470, a resonance circuit 487, a charging circuit 488, a battery 489, a communication circuit 490, an antenna 497, and/or a trigger circuit 498. In an embodiments, the processor 460 of the digital pen 400, at least part of the resonance circuit 487, and/or at least part of the communication circuit 490 may be configured on a printed circuit board or in the form of a chip. The processor 460, the resonance circuit 487, and/or the communication circuit 490 may be electrically connected to the memory 470, the charging circuit 488, the battery 489, the antenna 497, or the trigger circuit 498. The digital pen 400 according to an embodiment may include only a resonance circuit and a button.

The processor 460 may include a customized hardware module or a generic processor configured to execute software (e.g., application). The processor may include a hardware component (function) or a software element (program) including at least one of various sensors provided in the digital pen 400, a data measurement module, an input/output interface, a module configured to manage the state or environment of the digital pen 400, or a communication module. The processor 460 may include one or a combination of two or more of, for example, hardware, software, or firmware. The processor 460 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. According to an embodiment, the processor 460 may receive a proximity signal corresponding to an electromagnetic field signal generated from a digitizer included in a display module 160 of an electronic device (e.g., the electronic device 101 in FIG. 1) through the resonance circuit 487. When the proximity signal is identified, the resonance circuit 487 may be controlled to transmit an electromagnetic resonance (EMR) input signal to the electronic device 101.

The memory 470 may store information related to the operation of the digital pen 400. For example, the information may include information for communication with the electronic device 101 and frequency information associated with an input operation of the digital pen 400.

The resonance circuit 487 may include at least one of a coil, an inductor, or a capacitor. The resonance circuit 487 may be used by the digital pen 400 to generate a signal including a resonance frequency. For example, in order to generate the signal, the digital pen 400 may use at least one of an electro-magnetic resonance (EMR) method, an active electrostatic (AES) method, or an electrically coupled resonance (ECR) method. When the digital pen 400 transmits a signal by an EMR method, the digital pen 400 may generate a signal including a resonant frequency based on an electromagnetic field generated by an inductive panel of the electronic device 101. When the digital pen 400 transmits a signal by the AES method, the digital pen 400 may generate a signal using capacity coupling with the electronic device 101. When the digital pen 400 transmits a signal by the ECR method, the digital pen 400 may generate a signal including a resonant frequency based on an electric field generated by a capacitive device of the electronic device 101. According to an embodiment, the resonance circuit 487 may be used to change the intensity or frequency of the electromagnetic field depending on a user's operating state. For example, the resonance circuit 487 may provide frequencies for recognizing a hovering input, a drawing input, a button input, or an erasing input.

When the charging circuit 488 is connected to the resonance circuit 487 based on a switching circuit, a resonance signal generated by the resonance circuit 487 may be rectified into a DC signal and may be provided to the battery 489. According to an embodiment, the digital pen 400 may identify whether the digital pen 400 is inserted into the protection cover (e.g., the electronic device 300 in FIG. 5) using the voltage level of the DC signal detected by the charging circuit 488.

The battery 489 may be configured to store power required for operation of the digital pen 400. The battery may include, for example, a lithium-ion battery or a capacitor, and may be rechargeable or replaceable. According to an embodiment, the battery 489 may be charged using power (e.g., a DC signal (DC power)) supplied from the charging circuit 488.

The communication circuit 490 may be configured to perform a wireless communication function between the digital pen 400 and the communication module (e.g., the communication module 190 in FIG. 1) of the electronic device (e.g., the electronic device 101 in FIG. 1). According to an embodiment, the communication circuit 490 may transmit state information and input information of the digital pen 400 to the electronic device 101 using a short-range communication method. For example, the communication circuit 490 may transmit, to the electronic device 101, direction information of the digital pen 400 (e.g., motion sensor data) acquired through the trigger circuit 498, voice information input via a microphone, or information on the remaining amount of the battery 489. As an example, the short-range communication method may include at least one of Bluetooth, Bluetooth Low Energy (BLE), or wireless LAN.

The antenna 497 may be used to transmit/receive a signal or power to/from the outside (e.g., the electronic device 101). According to an embodiment, the digital pen 400 may include a plurality of antennas 497 and may select at least one suitable antenna 497 for the communication method from among the plurality of antennas 497. Via the selected at least one antenna 497, the communication circuit 490 may exchange a signal or power with an external electronic device.

The trigger circuit 498 may include at least one button or a sensor circuit. According to an embodiment, the processor 460 may identify an input method (e.g., touch or push) or the type (e.g., an EMR button or a BLE button) of the button of the digital pen 400. According to an embodiment, the sensor circuit may generate an electrical signal or a data value corresponding to an internal operating state or an external environmental state of the digital pen 400. For example, the sensor circuit may include at least one of a motion sensor, a remaining battery capacity detection sensor, a pressure sensor, an optical sensor, a temperature sensor, a geomagnetic sensor, and a biometric sensor. According to an embodiment, the trigger circuit 498 may transmit a trigger signal to the electronic device 101 using an input signal of the button or a signal acquired through a sensor.

The configurations of the resonance circuit 487 and the battery 489 of FIG. 6 may be wholly or partly the same as the configurations of the coil 401 and the capacitors 402, 403 of FIG. 5.

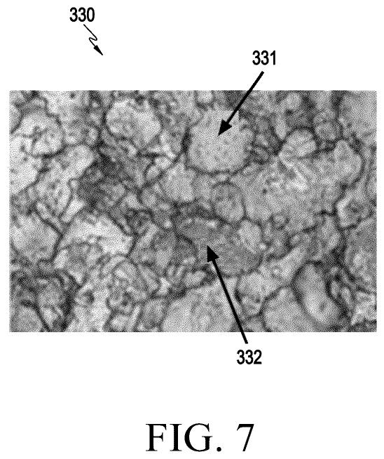

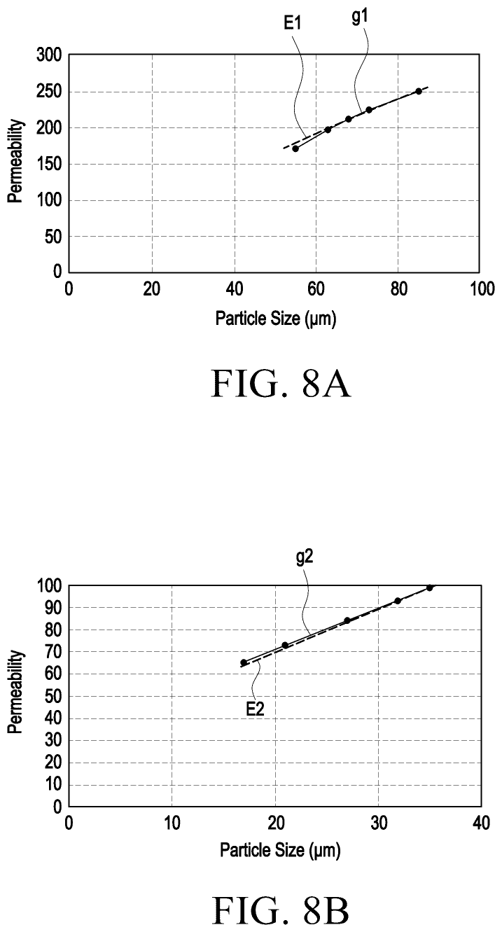

FIG. 7 is a diagram illustrating an enlarged view of an absorber sheet according to an embodiment of the disclosure. FIG. 8A is a graph illustrating the permeability of first particles of an absorber sheet according to an embodiment of the disclosure. FIG. 8B is a graph illustrating the permeability of second particles of an absorber sheet according to an embodiment of the disclosure. In FIGS. 8A and 8B, the Y-axis represents the permeability (unit: μ), and the X-axis represents the particle size of the particles (unit: μm).

Referring to FIG. 7, the absorber sheet 330 may include the first particles 331 and the second particles 332. The configuration of the absorber sheet 330 of FIG. 7 may be wholly or partly the same as the configuration of the absorber sheet 330 of FIG. 5. The structure of the absorber sheet 330 described with reference to FIG. 7 may be applied to the absorber sheet 330 described herein.

According to an embodiment, the absorber sheet 330 may have a structure for implementing a coefficient of performance and a performance retention rate. For example, the absorber sheet 330 may include first particles 331 and second particles 332 having different materials.

According to an embodiment, the first particles 331 may be made of a material for improving the permeability of the absorber sheet 330. The first particles 331 may include iron (Fe), silicon (Si), and aluminum (Al). For example, the first particles 331 may be an iron, silicon, and aluminum alloy powder. According to an embodiment, the first particles 331 may have a flake shape. For example, the first particles 331 may be an iron, silicon, and aluminum alloy powder processed into a flake shape. According to an embodiment, the particle size of the first particles 331 may be 90 μm or less. For example, the particle size of the first particles 331 may be 40 to 90 μm.

According to an embodiment, the second particles 332 may be manufactured from a material for improving the saturation magnetic flux density. The second particles 332 may include iron (Fe) and silicon (Si). According to an embodiment, the particle size of the second particles 332 may be 15 μm or more. For example, the particle size of the second particles 332 may be 20 to 40 μm. According to an embodiment, the particle size of the second particles 332 may be 15 to 40 μm. According to an embodiment, the second particles 332 may be positioned within empty spaces formed by the first particles 331.

According to an embodiment, the second particles 332 may have a flake shape. For example, the second particles 332 may be an iron and silicon alloy powder processed into a flake shape.

According to an embodiment, the permeability of the first particles 331 may be higher than the permeability of the second particles 332. According to an embodiment, the saturation magnetic flux density of the second particles 332 may be higher than the saturation magnetic flux density of the first particles 331. For example, the coefficient of performance of the second particles 332 may be higher than the coefficient of performance of the first particles 331.

According to an embodiment, the permeability of the first particles 331 may be about 200μ. The saturation magnetic flux density of the first particles 331 may be about 0.8 T. According to an embodiment, the permeability of the second particles 332 may be about 60 to 80μ. The saturation magnetic flux density of the second particles 332 may be about 1.6 T.

Herein, the particle size (or grain size) of the first particles 331 and/or the second particles 332 may be defined by the method of D50. For example, the particle size of the first particles 331 may be referred to as a particle size corresponding to an intermediate value.

According to an embodiment, the absorber sheet 330 including the first particles 331 and the second particles 332 may have a predetermined permeability. For example, the absorber sheet 330 may have a permeability for improving the inductance of a digital pen (e.g., the digital pen 400 of FIG. 5 and/or FIG. 6). According to an embodiment, the absorber sheet 330 may have a permeability of 100μ or more. In order to improve the inductance of the digital pen 400, the coefficient of performance (CP) of the absorber sheet 330 may satisfy Equation 1 below.

$$C P = D \times P \qquad [ Equation 1 ]$$

In Equation 1, D refers to the thickness D of the absorber sheet 330, and P refers to the permeability of the absorber sheet 330. For example, the coefficient of performance (CP) of the absorber sheet 330 may be the product of the thickness D of the absorber sheet 330 and the permeability P of the absorber sheet 330. The coefficient of performance (CP) of the absorber sheet 330 may be about 4,700 or more. In an embodiment, the coefficient of performance (CP) of the absorber sheet 330 may be about 4,750. In order to make the electronic device (e.g., the electronic device 101 in FIG. 2) thinner and lighter, the thickness D of the absorber sheet 330 may be limited. For example, the thickness D of the absorber sheet 330 may be about 40 to 50 μm.

The coefficient of performance (CP) of the absorber sheet 330 may be selectively designed. In an embodiment, the coefficient of performance (CP) of the absorber sheet 330 may be about 3,000 or more. Since the coefficient of performance (CP) of the absorber sheet 330 is designed to be 3,000 or higher, it is possible to detect an input (e.g., hovering) of the digital pen 400 by the digitizer 320.

According to an embodiment, the absorber sheet 330 may have a predetermined saturation flux density. The absorber sheet 330 may have a saturation flux density to reduce inductance drop due to other components (e.g., the electronic component 370 and/or the hinge structure 380). According to an embodiment, the absorber sheet 330 may have a saturation flux density of 1.5 T or more.

According to an embodiment, since the absorber sheet 330 has the predetermined saturation flux density, the performance retention rate of the absorber sheet 330 may satisfy Equation 2 below. The performance retention rate of the absorber sheet 330 may be a ratio of a first permeability in a state in which a magnetic field of a predetermined level (e.g., 50 Gauss) is applied to the absorber sheet 330 to a second permeability in a state in which the magnetic field of the predetermined level is not applied to the absorber sheet 330. According to an embodiment, the magnetic field of the predetermined level applied to the absorber sheet 330 is an example. For example, the predetermined level of the magnetic field may be the minimum value that requires shielding to maintain the performance of the digitizer 320 among the magnetic fields transmitted from a component of the electronic device 300 (e.g., the hinge structure 202 in FIG. 4) to the absorber sheet 330.

The performance retention rate (CM) of the absorber sheet 330 may satisfy Equation 2 below. The performance retention rate (CM) of the absorber sheet 330 may be referred to as a tolerance coefficient.

$$C M = \frac{CP 1}{CP 2} \qquad [ Equation 2 ]$$

In Equation 2 above, CP1 may be referred to as the coefficient of performance of the absorber sheet 330 in a state in which a magnetic field of a predetermined level (e.g., 50 Gauss or 40 Gauss) is applied to the absorber sheet 330. CP2 may be referred to as the coefficient of performance coefficient of the absorber sheet 330 in a state in which the magnetic field of the predetermined level (e.g., 50 Gauss or 40 Gauss) is not applied to the absorber sheet 330. The numerical values of the level of the magnetic field applied to the absorber sheet 330 is an example. For example, CP1 may be the coefficient of performance of the absorber sheet 330 that is facing or adjacent to the electronic component 370 or the hinge structure 380 configured to generate a magnetic field. CP2 may be referred to as the coefficient of performance of an absorber sheet 330 that is not facing or adjacent to the electronic component 370 or the hinge structure 380 configured to generate a magnetic field, or the coefficient of performance detected using the absorber sheet 330 in the state in which the electronic component 370 or the hinge structure 380 is removed.

According to an embodiment, the absorber sheet 330 may have a performance retention rate of 30% or more. Since the absorber sheet 330 has a performance retention rate of 30% or more, the accuracy of position determination of the digital pen 400 of the processor (e.g., the processor 120 in FIG. 1) may be increased. For example, as the performance retention rate is higher, the change in the permeability of the absorber sheet 330 may be reduced, and the accuracy of calibration of the processor 120 may be improved.

The design of the performance retention rate of the absorber sheet 330 may be changed. For example, in an embodiment, the absorber sheet 330 may have a performance retention rate of 20% or more. In an embodiment, the absorber sheet 330 may have a performance retention rate of 15% or more.

According to an embodiment, the absorber sheet 330 may include first particles 331 and second particles 332 having a composition ratio for implementing a coefficient of performance coefficient and a performance retention rate. According to an embodiment, the weight ratio of the first particles 331 to the absorber sheet 330 may be 30 w % or less. According to an embodiment, the weight ratio of the second particles 332 to the absorber sheet 330 may be 70 w % or more. According to an embodiment, the mixing ratio of the second particles 332 may be about 80% to 90%. According to an embodiment, the ratio of the second particles 332 to the first particles 331 may be 7:3 or higher. According to an embodiment, the absorber sheet 330 may include the first particles 331 and the second particles 332.

According to an embodiment, the permeability P of the absorber sheet 330 may be determined based on the ratio of the first particles 331 and the second particles 332. For example, the permeability P of the absorber sheet 330 may be the sum of the product of the permeability of the first particles 331 and the ratio of the first particles 331 and the product of the permeability of the second particles 332 and the ratio of the second particles 332.

Referring to FIG. 8A, the permeability of the first particles 331 may be changed based on the particle size of the first particles 331. For example, referring to a first graph g1 showing the first permeability according to the first particle size d1 of the first particles 331, the first permeability E1 of the first particles 331 may substantially satisfy Equation 3 below.

$$E 1 = 50 + 2.5 \times d 1 \qquad [ Equation 3 ]$$

Referring to FIG. 8B, the permeability of the second particles 332 may be changed based on the particle size of the second particles 332. For example, a second graph g2 shows the second permeability E2 according to the second particle size d2 of the second particles 332. The second permeability E2 of the second particles 332 may substantially satisfy Equation 4 below.

$$E 2 = 30 + 1.88 \times d 2 \qquad [ Equation 4 ]$$

The ratios, the permeabilities, and/or the particle sizes of the first particles 331 and the second particles 332 of the absorber sheet 330 may be selected to implement a coefficient of performance and a performance retention rate. For example, the ratios, the permeabilities, and/or the particle sizes of the first particles 331 and the second particles 332 may be selected to implement a coefficient of performance of a predetermined magnitude (e.g., 4750) and a performance retention rate of a predetermined level (e.g., 20% or 30%) or more. According to an embodiment, the ratios, the permeability rates, and/or the performance retention rates of the first particles 331 and the second particles 332 may be changed based on the thickness of the absorber sheet 330. According to an embodiment, when a magnetic field of a predetermined level (e.g., 50 Gauss) is applied to the absorber sheet 330, the permeability of the first particles 331 may be reduced by about 87%, and the permeability of the second particles 332 may be reduced by about 64%.

First to sixth embodiments are example embodiments that describe the structure of the absorber sheets 330.

According to an embodiment, when a magnetic field of a predetermined level (e.g., 50 Gauss) is applied to the first particles 331, the performance retention rate of the first particles 331 may be 13%. When the magnetic field of the predetermined level (e.g., 50 Gauss) is applied to the second particles 332 of the second embodiment, the performance retention rate may be about 36%.

According to an embodiment (e.g., a first embodiment, a second embodiment, and a third embodiment), the thickness of the absorber sheet 330 may be about 50 μm.

In an embodiment (e.g., a first embodiment), the absorber sheet 330 may not include the first particles 331 and may include the second particles 332. The particle size of the second particles 332 may be about 34.6 μm, and the permeability may be 95.048μ. The absorber sheet 330 of the first embodiment may have a permeability of about 95μ, a coefficient of performance of about 4750, and may have a permeability of about 34μ and a performance retention rate of about 36% when a magnetic field of a predetermined level (e.g., 50 Gauss) is applied.

In an embodiment (e.g., the second embodiment), the absorber sheet 330 may include first particles 331 having a weight ratio of about 11 w % and second particles 332 having a weight ratio of about 89 w %. The first particles 331 may have a particle size of about 76 μm and a permeability of about 240μ. The second particles 332 may have a particle size of about 25 μm and a permeability of about 77μ. The absorber sheet 330 of the second embodiment may have a permeability of about 95μ, a coefficient of performance of about 4747, and may have a permeability of about 28μ and a performance retention rate of about 30% when a magnetic field of a predetermined level (e.g., 50 Gauss) is applied.

In an embodiment (e.g., the third embodiment), the absorber sheet 330 may include first particles 331 having a weight ratio of about 25 w % and second particles 332 having a weight ratio of about 75 w %. The first particles 331 may have a particle size of about 20 μm and a permeability of 100μ. The second particles 332 may have a particle size of about 33.7 μm and a permeability of about 93.356μ. The absorber sheet 330 of the third embodiment may have a permeability of about 95μ, a coefficient of performance of about 4751, and may have a permeability of about 28μ and a performance retention rate of about 30% when a magnetic field of a predetermined level (e.g., 50 Gauss) is applied.

According to an embodiment (e.g., a fourth embodiment, a fifth embodiment, and a sixth embodiment), the thickness of the absorber sheet 330 may be about 40 μm.

In an embodiment (e.g., the fourth embodiment), the absorber sheet 330 may not include the first particles 331 and may include the second particles 332. The second particles 332 may have a particle size of about 47.3 μm and a permeability of about 118.92μ. The absorber sheet 330 of the fourth embodiment may have a permeability of about 119μ, a coefficient of performance of about 4757, and may have a permeability of about 43μ and a performance retention rate of about 36% when a magnetic field of a predetermined level (e.g., 50 Gauss) is applied.

In an embodiment (e.g., the fifth embodiment), the absorber sheet 330 may include first particles 331 having a weight ratio of about 13.3 w % and second particles 332 having a weight ratio of about 86.7 w %. The first particles 331 may have a particle size of about 80 μm and a permeability of about 250μ. The second particles 332 of the fifth embodiment may have a particle size of about 25 μm and a permeability of about 77μ. The absorber sheet 330 of the fifth embodiment may have a permeability of about 95μ, a coefficient of performance of about 4750, and may have a permeability of about 35μ and a performance retention rate of about 30% when a magnetic field of a predetermined level (e.g., 50 Gauss) is applied.

In an embodiment (e.g., the sixth embodiment), the absorber sheet 330 may include first particles 331 having a weight ratio of about 25 w % and second particles 332 having a weight ratio of about 75 w %. The first particles 331 may have a particle size of about 20 μm and a permeability of 100μ. The second particles 332 may have a particle size of about 50.6 μm and a permeability of about 125.128μ. The absorber sheet 330 of the sixth embodiment may have a permeability of about 119μ, a coefficient of performance of about 4754, and may have a permeability of about 37μ and a performance retention rate of about 31% when a magnetic field of a predetermined level (e.g., 50 Gauss) is applied.

The structures of the first particles 331 and the second particles 332 of the absorber sheets 330 described in the first to sixth embodiments are examples. For example, the absorber sheet 330 may be selected in various ways as long as it has a coefficient of performance of 4750 and a performance retention rate of 30% or more.

According to an embodiment, the absorber sheet 330 may include a polymer binder (not illustrated). For example, the absorber sheet 330 may be manufactured using a coating-pressing process together a the polymer binder. According to an embodiment, the absorber sheet 330 may be referred to as an absorber film.

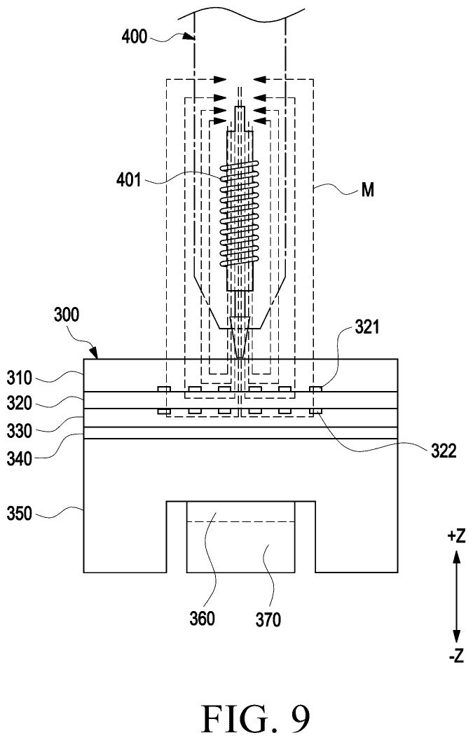

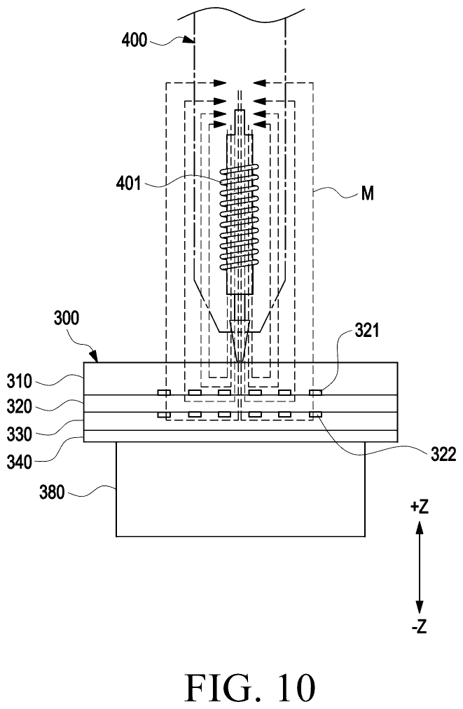

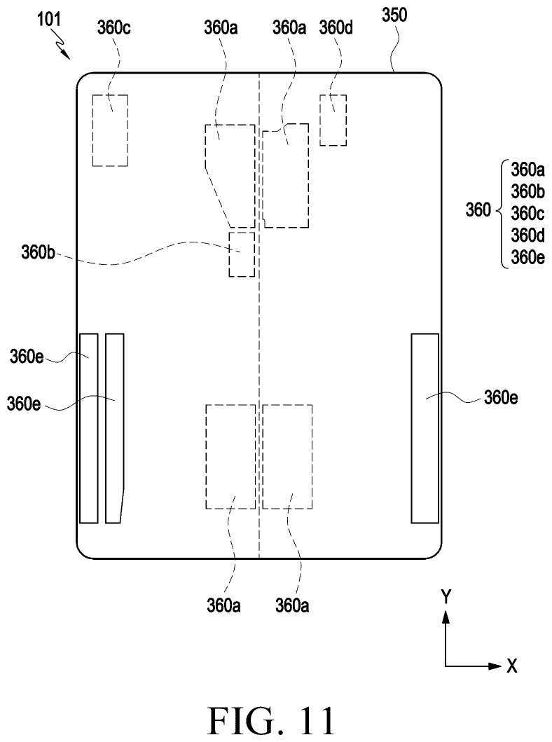

FIG. 9 is a cross-sectional view of an electronic device including an electronic component according to an embodiment of the disclosure. FIG. 10 is a cross-sectional view of an electronic device including a hinge structure according to an embodiment of the disclosure. FIG. 11 is a diagram illustrating a shielding member attached to a housing according to an embodiment of the disclosure.

Referring to FIG. 9, FIG. 10 and/or FIG. 11, the electronic device 300 may include a display 310, a digitizer 320, an absorber sheet 330, a metal sheet 340, a housing 350, a shielding member 360, and an electronic component 370. The electronic device 300 may detect an input of a digital pen 400. The configurations of the electronic device 300, the display 310, the digitizer 320, the absorber sheet 330, the metal sheet 340, the housing 350, the digital pen 400, and the coil 401 of FIG. 9, FIG. 10, and/or FIG. 11 may be wholly or partly the same as the configurations of the electronic device 300, the display 310, the digitizer 320, the absorber sheet 330, the metal sheet 340, the housing 201, the digital pen 400, and the coil 401 of FIG. 4 and/or FIG. 5.

According to an embodiment, the display 310, the digitizer 320, the absorber sheet 330, and/or the metal sheet 340 may be disposed on the housing 350. The housing 350 may be a support area (e.g., the first support area 212 and/or the second support area 222 in FIG. 4).

According to an embodiment, the shielding member 360 may reduce a magnetic field transmitted to the digitizer 320. For example, the shielding member 360 may be positioned between the digitizer 320 and an electronic component 370 that includes a magnet or is configured to generate a magnetic field. The shielding member 360 may be positioned between the housing 350 and the electronic component 370.

According to an embodiment (e.g., FIG. 11), the shielding member 360 may include a plurality of shielding members 360a, 360b, 360c, 360d, and 360e for shielding a plurality of electronic components 370. For example, the shielding member 360 may include a first shielding member 360a that covers at least a portion of a hinge structure (e.g., the hinge structure 202 in FIG. 4), a second shielding member 360b that covers at least a portion of a Hall sensor (e.g., the sensor module 176 in FIG. 1), a third shielding member 360c that covers at least a portion of a camera module (e.g., the camera module 206 in FIG. 2), a fourth shielding member 360d that covers at least a portion of a receiver (e.g., the audio module 170 in FIG. 1), and/or a fifth shielding member 360e that covers at least a portion of an attachment magnet for attachment of an accessory (e.g., the digital pen 400 in FIG. 5).

According to an embodiment, at least one of the plurality of shielding members 360a, 360b, 360c, 360d, and 360e may be omitted. For example, if the coefficient of performance and the performance retention rate of the absorber sheet 330 are greater than or equal to predetermined levels, the shielding member 360 for shielding the magnetic field of the electronic component 370 may not be required. According to an embodiment, the first to fourth shielding members 360a, 360b, 360c, and 360d may be omitted. For example, at least a portion of the electronic component 370 may be directly attached to the bottom of the housing 350 (in the −Z direction).

According to an embodiment, due to the absorber sheet 330, the thickness of the shielding member 360 may be reduced. As the thickness of the shielding member 360 is reduced, the inner space of the electronic device 300 may be increased, and the weight of the electronic device 300 may be reduced.

According to an embodiment, the shielding member 360 may be made of a material for shielding a magnetic field transmitted to an electronic component. For example, the shielding member 360 may be a soft magnetic material. The shielding member 360 may include at least one of a cold-rolled steel sheet (steel plate cold commercial, (SPCC)) or a resin material (e.g., acrylonitrile butadiene styrene (ABS)). According to an embodiment, the maximum relative magnetic permeability of the shielding member 360 may be 3,000 to 10,000. The thickness of the shielding member 360 may be 0.2 mm to 5 mm. The saturation flux density of the shielding member 360 may be 1.7 T to 2.3 T. The coercive force of the shielding member 360 may be 380 A/m.

According to an embodiment, the electronic component 370 may be a component configured to generate a magnetic field. For example, the electronic component 370 may be a camera (e.g., the camera module 206 in FIG. 3), a Hall sensor (e.g., the sensor module 176 of FIG. 1), a hinge structure (e.g., hinge structure 202 in FIG. 4), a motor, and/or an attachment magnet for attachment an external accessory. The electronic component 370 may be positioned under the shielding member 360.

According to an embodiment, the digitizer 320, the absorber sheet 330, and the metal sheet 340 may be connected to the hinge structure 380. The hinge structure 380 may be positioned under the absorber sheet 330 (in the −Z direction). According to an embodiment, at least a portion of the hinge structure 380 may be made of a magnetic material. The absorber sheet 330 may reduce interference of the digitizer 320 due to the magnetic field generated from the hinge structure 380.

The electronic device may detect the magnetic field generated using an input device (e.g., a digital pen or a stylus pen) using a digitizer to recognize the coordinates of the input device. The electronic device using the digitizer may include an absorber sheet to reduce inductance drop or eddy current generation caused by a metal component. The absorber sheet may have a relatively high permeability to improve the sensitivity of the input device. However, when a magnetic field of a predetermined level or more is formed around peripheral components of the absorber sheet, the effective permeability of the absorber sheet may decrease, which may result in a decrease in the absorber function, a decrease in the sensitivity of the digitizer substrate, and a decrease in the accuracy of position determination of the input device.

In order to maintain the effective permeability of the absorber sheet, the electronic device may include a shielding member positioned around a component capable of generating a magnetic force. However, the thickness and/or the weight of the electronic device may increase due to the shielding member, and the internal space of the electronic device may be reduced.

According to an embodiment of the disclosure, it is possible to provide an electronic device that includes an absorber sheet having improved responsiveness to performance degradation due to an external magnetic field while reducing inductance drop and/or eddy current generation caused by a metal component. For example, the absorber sheet of the disclosure may have a coefficient of performance and a performance retention rate greater than or equal to predetermined levels.

Since the absorber sheet has a performance retention rate greater than or equal to a predetermined level, the number and/or sizes of shielding members for shielding a magnetic field of a magnetic body may be reduced.

The problems that the disclosure seeks to address are not limited to the aforementioned problems, and may be expanded in various ways without departing from the spirit and scope of the disclosure.

According to an example embodiment of the disclosure, an electronic device (e.g., the electronic device 101 in FIG. 2) may include: a housing (e.g., the housing 201 in FIG. 2), a display (e.g., the display 230 in FIG. 2), a digitizer (e.g., the digitizer 320 in FIG. 5) positioned under the display, an absorber sheet (e.g., the absorber sheet 330 in FIG. 5) positioned under the digitizer, and a metal sheet (e.g., the metal sheet 340 in FIG. 5) positioned under the absorber sheet. The absorber sheet may include first particles (e.g., the first particles 331 in FIG. 7) including iron, silicon, and aluminum, and second particles (e.g., the second particles 332 in FIG. 7) including iron and silicon. The weight ratio of the second particles to the absorber sheet may be 70 w % or more.

According to an example embodiment, a first permeability of the absorber sheet in a state in which a magnetic field of a specified level (e.g., 50 Gauss) is applied to the absorber sheet is at least 20% of a second permeability of the absorber sheet in a state in which the magnetic field is not applied.

According to an example embodiment, a first size of the first particles may be 90 μm or less. According to an example embodiment, in the electronic device, a second size of the second particles is 15 μm or more.

According to an example embodiment, the absorber sheet may be positioned between the digitizer and the housing.

According to an example embodiment, a coefficient of performance, which is a product of a thickness of the absorber sheet and a permeability of the absorber sheet, may be 3,000 or more. Since the absorber sheet has the coefficient of performance of 3000 or more, the performance of the digitizer may be improved.

According to an example embodiment, the metal sheet may include copper.

According to an example embodiment, the housing may include a first housing (e.g., the first housing 210 in FIG. 2) and a second housing (e.g., the second housing 220 in FIG. 2). The display may include a first display area (e.g., the first display area 231 in FIG. 2) connected to the first housing, a second display area (e.g., the second display area 232 in FIG. 2) connected to the second housing, and a folding area (e.g., the folding area 233 in FIG. 2) positioned between the first display area and the second display area. The electronic device may include a hinge structure comprising a hinge (e.g., the hinge structure 202 in FIG. 4) connecting the first housing and the second housing.

According to an example embodiment, the hinge structure may be positioned under the absorber sheet.

According to an example embodiment, the electronic device may include a shielding member comprising a magnetic material positioned under the absorber sheet, in which the shielding member (e.g., the shielding member 360 in FIG. 9) includes a cold-rolled steel sheet or a resin material.

According to an example embodiment, the electronic device may include at least one processor, comprising processing circuitry (e.g., the processor 120 in FIG. 1), individually and/or collectively, configured to determine the position of an input device using the digitizer.

According to an example embodiment, the electronic device may further include an electronic component comprising an electronic circuit (e.g., the electronic component 370 in FIG. 9) configured to generate a magnetic field, in which the electronic component is positioned under the absorber sheet.

According to an example embodiment, the electronic component may include at least one of a Hall sensor (e.g., the sensor module 176 in FIG. 1), a camera module (e.g., the camera module 206 in FIG. 2), or a receiver (e.g., the audio module 170 in FIG. 1).

According to an example embodiment, the permeability of the first particles may be higher than the permeability of the second particles. The saturation flux density of the second particles may be higher than the saturation flux density of the first particles.

According to an example embodiment, the first particles and the second particles may have a flake shape.

According to an example embodiment, the weight ratio of the second particles to the absorber sheet may be 80 to 90 w %.

According to an example embodiment, a foldable electronic device (e.g., the electronic device 101 in FIG. 2) may include: a housing (e.g., the housing 201 in FIG. 2) including a first housing (e.g., the first housing 210 in FIG. 2) and a second housing (e.g., the second housing 220 in FIG. 2), a display (e.g., the display 230 in FIG. 2) including a first display area (e.g., the first display area 231 in FIG. 2) positioned on the first housing, a second display area (e.g., the second display area 232 in FIG. 2) positioned on the second housing, and a folding area (e.g., the folding area 233 in FIG. 2) positioned between the first display area and the second display area, a hinge structure comprising a hinge (e.g., the hinge structure 202 in FIG. 2) connecting the first housing and the second housing, in which at least a portion of the hinge structure is positioned under at least a portion of the folding area, a digitizer (e.g., the digitizer 320 in FIG. 5) positioned under the display, and an absorber sheet (e.g., the absorber sheet 330 in FIG. 5) positioned under the digitizer. The absorber sheet may include first particles (e.g., the first particles 331 in FIG. 7) including iron, silicon, and aluminum, and second particles (e.g., the second particles 332 in FIG. 7) including iron and silicon. The ratio of the second particles to the first particles may be 7:3 or higher.

According to an example embodiment, the first size of the first particles may be 90 μm or less, and the second size of the second particles may be 20 μm or more.

According to an example embodiment, the permeability of the absorber sheet may be 100μ or more, and the saturation flux density of the absorber sheet may be 1.5 T or more.

According to an example embodiment, the foldable electronic device may further include a metal sheet (e.g., the metal sheet 340 in FIG. 5) positioned under the absorber sheet, in which the metal sheet includes copper.

According to an example embodiment, the permeability of the first particles may be higher than the permeability of the second particles. The saturation flux density of the second particles may be higher than the saturation flux density of the first particles.

It may be apparent to one skilled in the technical field to which the disclosure belongs that the above-described electronic device including a digitizer according to the disclosure is not limited by the above-described embodiments and drawings, and can be variously substituted, modified, and changed within the technical scope of the disclosure. It will be further understood that any of the embodiment(s) described herein may be used in connection with any other embodiment(s) described herein.

What is claimed is:

1. An electronic device comprising:
a housing;
a display;
a digitizer positioned under the display;
an absorber sheet disposed under the digitizer; and
a metal sheet positioned under the absorber sheet,
wherein the absorber sheet comprises first particles containing iron, silicon, and aluminum, and second particles containing iron and silicon, and
wherein a ratio of the second particles to the first particles is 7:3 or higher.

2. The electronic device of claim 1, wherein a first permeability of the absorber sheet in a state in which a magnetic field of a specified level is applied to the absorber sheet is at least 20% of a second permeability of the absorber sheet in a state in which the magnetic field is not applied.

3. The electronic device according to claim 1, wherein a first size of the first particles is 90 μm or less, and a second size of the second particles is 15 μm or more.

4. The electronic device of claim 1, wherein the absorber sheet is positioned between the digitizer and the housing.

5. The electronic device of claim 1, wherein a coefficient of performance, which is a product of a thickness and permeability of the absorber sheet, is at least 3,000.

6. The electronic device of claim 1, wherein the metal sheet comprises copper.

7. The electronic device of claim 1, wherein the housing comprises a first housing and a second housing,
wherein the display comprises a first display area connected to the first housing, a second display area connected to the second housing, and a folding area positioned between the first display area and the second display area, and
wherein the electronic device further comprises a hinge structure comprising a hinge connecting the first housing and the second housing.

8. The electronic device of claim 7, wherein the hinge structure is positioned under the absorber sheet.

9. The electronic device according to claim 1, further comprising:
a shielding member comprising a soft magnetic material positioned under the absorber sheet, the shielding member comprising a cold-rolled steel sheet or a resin material.

10. The electronic device according claim 1, further comprising:
at least one processor, comprising processing circuitry, individually and/or collectively, configured to determine a location of an input device using the digitizer.

11. The electronic device according to claim 1, further comprising:
an electronic component comprising an electronic circuit configured to generate a magnetic field and positioned under the absorber sheet.

12. The electronic device of claim 11, wherein the electronic component comprises at least one of a Hall sensor, a camera module comprising a camera, or a receiver.

13. The electronic device of claim 1, wherein the first particles have a permeability of higher than a permeability of the second particles, and
wherein a saturation flux density of the second particles is higher than a saturation flux density of the first particles.

14. The electronic device of claim 1, wherein the first particles and the second particles have a flake shape.

15. The electronic device of claim 1, wherein a weight ratio of the second particles in the absorber sheet is 80 to 90 w %.

16. A foldable electronic device comprising:
a housing comprising a first housing and a second housing;
a display comprising a first display area positioned on the first housing, a second display area positioned on the second housing and a folding area positioned between the first display area and the second display area;
a hinge structure comprising a hinge connecting the first housing and the second housing, at least a portion of the hinge is positioned under at least a portion of the folding area;
a digitizer positioned under the display; and
an absorber sheet positioned under the digitizer,
wherein the absorber sheet comprises first particles containing iron, silicon, and aluminum, and second particles containing iron and silicon, and
wherein a ratio of the second particles to the first particles is 7:3 or higher.

17. The foldable electronic device of claim 16, wherein a first size of the first particles is 90 μm or less, and a second size of the second particles is 20 μm or more.

18. The foldable electronic device of claim 16, wherein a permeability of the absorber sheet is 100μ or more, and a saturation flux density of the absorber sheet may be 1.5 T or more.

19. The foldable electronic device of claim 16, further comprising:
a metal sheet positioned under the absorber sheet, and comprising a copper.

20. The foldable electronic device of claim 16, wherein a permeability of the first particles is higher than a permeability of the second particles, and
wherein a saturation flux density of the second particles is higher than a saturation flux density of the first particles.
